(19) United States
(12) Patent Application Publication
(10) Pub. No.: US 2006/0105559 A1
(43) Pub. Date: May 18, 2006

(54) Ultrathin buried insulators in Si or Si-containing material

(75) Inventors: Tze-Chiang Chen, Yorktown Heights, NY (US); Bernard Steele Meyerson, Yorktown Heights, NY (US); Devendra Kumar Sadana, Pleasantville, NY (US)

Correspondence Address: IBM CORPORATION, T.J. WATSON RESEARCH CENTER, P.O. BOX 218, YORKTOWN HEIGHTS, NY, 10598, US

(73) Assignee: International Business Machines Corporation, Armonk, NY (US)

(21) Appl. No.: 10/990,300

(22) Filed: Nov. 15, 2004

(51) Int. Cl. H01L 21/44

(52) U.S. Cl. 438/607

(57) ABSTRACT

A method for forming an ultra thin buried oxide layer is described incorporating the steps of forming a first epitaxial layer containing Si on a Si containing substrate having a thickness from about 10 to about 300 angstroms thick, forming a second epitaxial layer containing Si having a thickness from about 100 angstroms to about 1 micron and annealing the substrate at a temperature from 1200° C. to 1400°0 C. in an oxygen containing atmosphere. The invention over comes the problem of the buried oxide breaking up into oxide islands during the anneal.

### FIELD OF THE INVENTION

This invention relates to Silicon-On-Insulator semiconductor substrates and more particularly to forming ultrathin buried oxide layers by the combination of ion implantation and oxygen diffusion.

### BACKGROUND OF THE INVENTION

Ultathin buried oxide layers with thicknesses in the range less than 300 angstroms are difficult to produce by the Separation by Implanted Oxygen (SIMOX) process. In the SIMOX process oxygen ions are implanted at elevated temperatures, such as at greater than 500° C. in a Si substrate to maintain crystallinity of the Si during implantation. Then, in order to create a buried oxide in the Si substrate, the substrate is annealed at temperatures greater than 1300° C. for several hours. However, because of high surface energy associated with an ultrathin buried oxide layer in Si, the buried oxide layer becomes unstable during the anneal and tends to break up into oxide islands.

### BRIEF DESCRIPTION OF THE DRAWING

These and other features, objects, and advantages of the present invention will become apparent upon consideration of the following detailed description of the invention when read in conjunction with the drawing in which:

FIG. 1 is a cross section view of a silicon wafer with Si epitaxial layers thereon.

FIG. 2 is a cross section view of a silicon wafer with a buried oxide layer and an oxide layer on the top.

FIG. 3 is a cross section view of a silicon wafer with Si epitaxial layers thereon with an oxygen profile superimposed.

FIG. 4 is a cross section view of a silicon wafer with a buried oxide layer and an oxide layer on the top.

### DESCRIPTION OF THE PREFERRED EMBODIMENTS

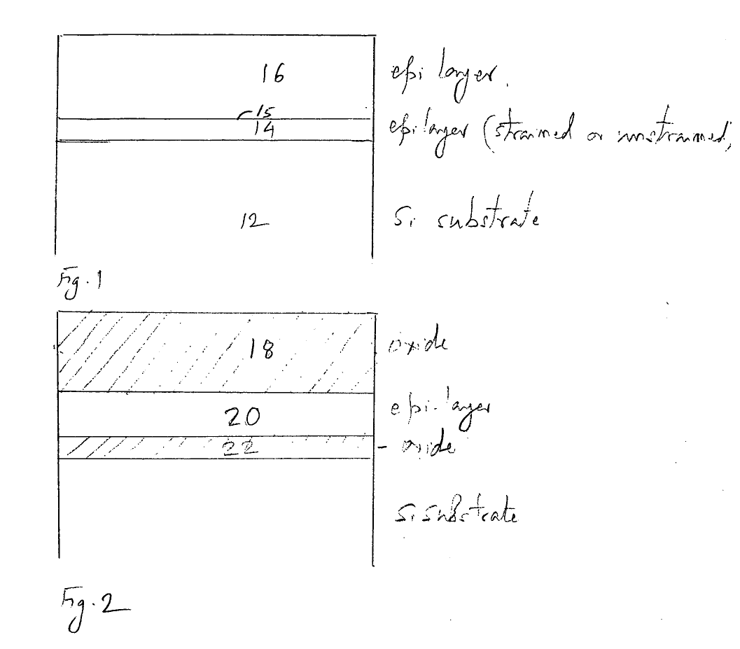

Referring to the drawing and in particular to FIG. 1, a Si containing wafer 12 is shown having a first epitaxial layer 14 with an upper surface 15 and an epitaxial Si containing layer 16 formed on surface 15. Epitaxial layer 14 has a thickness in the range from 10 to 300 angstroms. Epitaxial layer 16 has a thickness in the range from 100 angstroms to 1 micron. Layer 14 or layer 16 may contain Si only, isotopically pure Si or an alloy of such silicon such as Si—Ge or Si—C, oxygen doped or boron-doped Si. Istopically pure Si is Si of a single isotope in the range from 90 to 100% and preferably 99%. Layer 14 may be strained or unstrained depending on the lattice spacing of wafer 12 and layer 14 which in turn is dependent upon the composition. Ge has a lattice spacing of 1.04 that of Si. Si—C has a lattice spacing of 1.12 that of Si. Both the unstrained or strained layer 14 may contain oxygen gettering elements such as B, Al, Ti, etc.

FIG. 2 shows the embodiment of FIG. 1 after the step of thermal oxidation and oxygen diffusion at high temperature such as greater than 1300 C. Thermal oxide layer 18 is formed out of and on the remaining portion of layer 16 now referred to as layer 20. And during the step of thermal oxidation, oxygen diffuses through layers 18 and 20 and converts layer 14 shown in FIG. 1 into a buried oxide layer 22. The concentration of oxygen in the annealing atmosphere may be in the range from 0.1% to 100%. Argon may be the other constituent in the annealing atmosphere.

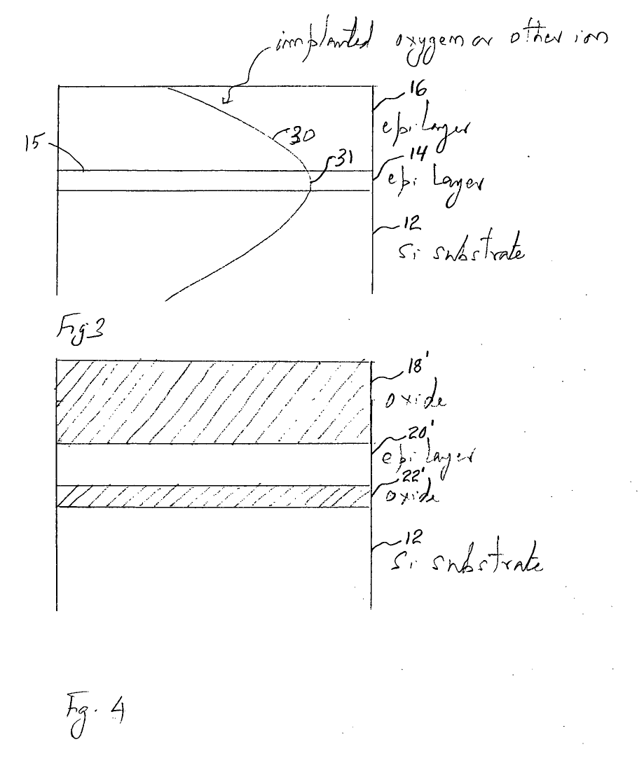

FIG. 3 shows oxygen implanted into the wafer of FIG. 1 having a concentration profile shown by curve 30 superimposed over the cross section. Ions of a selected element such as oxygen, nitrogen, carbon, aluminum, titanium and hydrogen are implanted as ions into the wafer wherein the ions are converted to atomic elements by recombination with an electron. The peak concentration occurs at layer 14 by adjusting the energy of the ions being implanted. The peak dose at layer 14, point 31 on curve 30, may be 2×10¹⁷ ions/cm². In FIG. 3 for curve 30, the ordinate represents depth and the abscissa represents concentration of implanted ions.

The ion selected is for two purposes, one to create damage in the crystal lattice of layer 14 to enhance oxygen diffusion at times oxygen is implanted and two, to getter oxygen (if an element other than oxygen is implanted). If the element implanted is not oxygen but one or more elements in combination such as B or Al, crystal lattice damage is formed in layer 14 as before and the implanted elements will provide a chemical affinity to getter oxygen. FIG. 4 is similar to FIG. 2 but shows the result of the implanted materials described with respect to FIG. 3 and after an anneal where oxygen is diffused into layer 14 from the surface. FIG. 4. shows the embodiment of FIG. 3 after the step of thermal oxidation and oxygen diffusion at high temperature such as greater than 1300° C. Thermal oxide layer 18′ is formed out of and on the remaining portion of layer 16 now referred to as layer 20′. And during the step of thermal oxidation, oxygen diffuses through layers 18′ and 20′ and converts layer 14 shown in FIG. 3 into buried oxide layer 22′.

While there has been described and illustrated a method for forming ultrathin buried oxide in Si containing wafers, it will be apparent to those skilled in the art that modifications and variations are possible without deviating from the broad scope of the invention which shall be limited solely by the scope of the claims appended hereto.

Having thus described our invention, what we claim as new and desire to secure by Letters Patent is:

1. A method for forming an ultra thin buried oxide layer in a Si containing substrate comprising the steps of:
forming a first epitaxial layer containing silicon on said substrate having a thickness in the range from about 10 to about 300 angstroms,
forming a second epitaxial layer containing silicon on said first epitaxial layer having a thickness in the range from about 100 angstroms to about 1 micron, and
annealing said substrate at a temperature in the range from about 1200° C. to 1400° C. in an oxygen containing atmosphere.

2. The method of claim 1 further including the step of:
implanting oxygen into said first epitaxial layer with an energy to place a peak concentration of oxygen at or near said first layer.

3. The method of claim 1 wherein said step of forming said first epitaxial layer includes the step of forming a strained layer.

4. The method of claim 3 wherein said first strained layer has an alloying composition to provide at least a 0.2% change in crystal lattice parameter when relaxed with respect to a lattice parameter of said substrate at the interface.

5. The method of claim 3 further including the step of relaxing said strained layer.

6. The method of claim 1 further including the step of doping said first epitaxial layer with boron.

7. The method of claim 1 further including the step of doping said first epitaxial layer with carbon.

8. The method of claim 1 further including the step of growing a third epitaxial layer below said first epitaxial layer wherein said third epitaxial layer contains silicon and carbon.

9. The method of claim 1 further including the step of growing a third epitaxial layer above said first epitaxial layer wherein said third epitaxial layer contains silicon and carbon.

10. The method of claim 1 further including the step of:
implanting a metal ion into said first epitaxial layer with an energy to place a peak concentration of metal at or near said first layer.

11. The method of claim 1 further including the step of:
doping said first epitaxial layer with an element having a higher affinity for oxygen than silicon.

12. The method of claim 11 further including the step of:
selecting said element from the group consisting of Al, Cr, Ti, Fe, Ga and B.

13. The method of claim 1 further including the steps of:
forming a patterned mask over said second epitaxial layer having openings therein and implanting oxygen through said openings into said first epitaxial layer with an energy to place a peak concentration of oxygen at or near said first layer whereby after annealing said ultra thin buried oxide layer is formed below said openings.

14. The method of claim 13 further including the step of removing said mask.

15. The method of claim 1 wherein said step of forming a second epitaxial layer includes forming a layer selected from the group consisting of Si only, Si of a given isotope greater than 99%, SiGe, SiC, and boron doped Si.
